(19) United States
(12) Patent Application Publication
(10) Pub. No.: US 2021/0028382 A1
(43) Pub. Date: Jan. 28, 2021

(54) INVERTED, SEMITRANSPARENT SMALL MOLECULE PHOTOVOLTAIC CELLS

(71) Applicant: The Regents of the University of Michigan, Ann Arbor, MI (US)

(72) Inventors: Stephen R. FORREST, Ann Arbor, MI (US); Xin XIAO, aNN aRBOR, MI (US); Kyusang LEE, Ann Arbor, MI (US)

(73) Assignee: The Regents of the University of Michigan, Ann Arbor, MI (US)

(21) Appl. No.: 16/946,709

(22) Filed: Jul. 1, 2020

Related U.S. Application Data
(60) Provisional application No. 62/869,359, filed on Jul. 1, 2019.

(51) Int. Cl. H01L 51/42; H01L 27/30; H01L 51/44; H01L 51/00

(52) U.S. Cl. CPC H01L 51/4253; H01L 27/302; H01L 51/442; H01L 2251/308; H01L 51/0068; H01L 51/0071; H01L 51/0046

(57) ABSTRACT

Semitransparent organic photovoltaic (OPV) cells provide integrated photovoltaic needs, such as use on windows and other architectural surfaces. These cells can achieve high power conversion efficiency and supply acceptable transparency. Inverted, semitransparent OPV cells are provided that include a mixed organic heterojunction layer or a planar-mixed heterojunction layer. These cells can additionally be used to create a tandem cell, which absorbs light over a broader range of wavelengths.

This application claims the benefit of priority of U.S. Provisional Patent Application No. 62/869,359 filed on Jul. 1, 2019 the contents of which are incorporated herein by reference in their entirety.

This invention was made with government support under DE-EE0005310 and DE-EE0006708 awarded by the U.S. Dept. of Energy. The government has certain rights in the invention.

Semitransparent organic photovoltaic (OPV) cells are of interest due to their potential for fulfilling building integrated PV needs such as deployment on windows and other architectural surfaces. Moreover, semitransparent OPV cells can also be integrated into tandem- and multi-junction structures to achieve a high power conversion efficiency (PCE) along with acceptable transparency for these applications. However, the PCE of semitransparent OPV cells remains relatively low since they have been primarily based on bilayer or mixed heterojunction (HJ) structures.

The present disclosure is directed to inverted, semitransparent photovoltaic cells, particularly semitransparent OPVs based on both mixed and hybrid planar-mixed heterojunctions (PM-HJ). The device structures are inverted to allow for the use of transparent indium tin oxide (lTO) contacts for both anode and cathode. Cathode contact is made on the substrate surface using a hole blocking/electron selective sol-gel ZnO layer as a cathode buffer on top of an ITO contact The ZnO has a high electron mobility⁹ of ˜10 cm²/V·s. 98% transmission in the visible and near infrared (NIR) spectral regions, and a work function of 4.5 eV¹⁰, leading to efficient electron collection and low optical loss. In addition, ZnO-based inverted structures eliminate thin but optically lossy metal layers that have been reported previously. It is worth noting that conventional OPV structures using wide energy gap molecules, e.g. bathophenanthroline (BPhen), as cathode buffers cannot employ symmetric ITO contacts due to the lack of electron-transporting defect states induced by the electrode deposition, whereas inverted structures enable the implementation of metal oxides, e.g. MoO₃, as the buffer for the top electrode to efficiently extract charge carriers without the concern of defect states.

### BRIEF DESCRIPTION OF TABLES AND FIGURES

Table I depicts performance of inverted, semitransparent OPV cells

FIG. 1A depicts current density-voltage characteristics of semitransparent OPV cells with different active layer thicknesses, x. Inset: (left) Transmission spectrum of 30 nm DBP:C₇₀ mixed film; (right) Photograph of 30 nm DBP:C₇₀ film on a quartz substrate. FIG. 1B depicts external quantum efficiency (EQE) spectra for the same devices vs. x.

FIG. 2 depicts the power conversion efficiency, PCE (left axis) and average optical transmission between the wavelengths of λ=400 nm to 700 nm (right axis) vs. thickness of the photoactive layers for mixed HJ OPV cells.

FIG. 3A depicts current density-voltage characteristics of inverted semitransparent mixed HJ (hollow squares) and PM-HJ (hollow circles) OPVs under simulated AM 1.5G illumination at one sun intensity. FIG. 3B depicts absorption (left axis), EQE and internal quantum efficiency (IQE, right axis) spectra of mixed and PM-HJ cells.

FIG. 4A depicts current density-voltage characteristics of inverted semitransparent single junction and tandem OPV cells. Hollow circles, squares, triangles, and inverted triangles represent experimental data of the front, back sub-cells used in the tandem, the tandem cell via substrate illumination, and the same tandem under top illumination, respectively. Lines are calculated characteristics following previously described methods. Inset: Calculation of the absorbed optical power (unit: mW/(cm² nm)) distribution inside the tandem cells illuminated via either the cathode (left) or anode (right) contact surfaces. FIG. 4B depicts the EQE (left axis) vs. wavelength for semitransparent single junction and tandem cells (circles: front cell; squares: back cell; triangles: tandem) and transmission spectrum (right axis) of the tandem cell. Inset: Photograph of DTDCTB:C₆₀ (left), DBP:C₇₀ (middle), and tandem (right) films.

The inverted semitransparent PM-HJ OPV cells exhibit PCE=3.9±0.2% under simulated AM 1.5G illumination at one sun intensity with an average transmission of T̅=51±2% across the visible. This corresponds to >10% higher PCE than obtained for mixed HJ cells. This improvement is primarily due to improved charge collection efficiency and reduced series resistance in the PM-HJ architecture. Also disclosed are inverted semitransparent tandem cells incorporating two PM-HJ sub-cells that have absorption maxima in different regions of the solar spectrum. The optimal tandem cell reaches PCE=5.3±0.3% under simulated AM 1.5G illumination at one sun intensity, with T̅=31±1% across the visible, with similar performance whether illuminated via either the top contact or substrate surfaces. These results show a clear tradeoff between transparency and efficiency. Single junction cells can have an attractive and selectable hue adapted to a particular application, whereas the more absorptive tandem cell is optimized for efficiency while taking on a neutral tone.

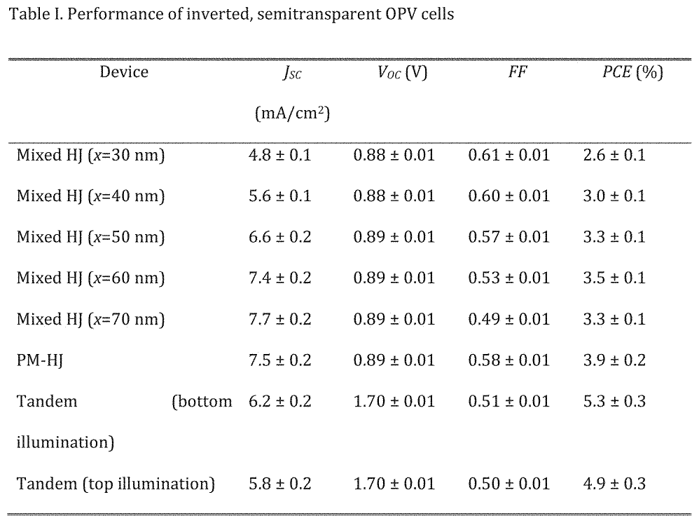

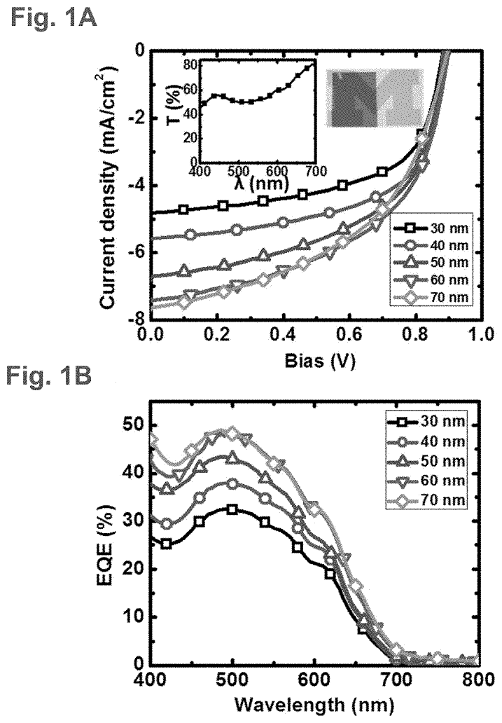

In a first embodiment of the present disclosure, inverted semitransparent mixed HJ OPV cells are fabricated based on the donor, tetraphenyldibenzoperiflanthene (DBP), and the acceptor, C₇₀. The first embodiment of the present disclosure is thus directed to a semitransparent photovoltaic cell, comprising a cathode layer of indium tin oxide; a cathode buffer layer comprised of ZnO, located between the cathode layer and a mixed heterojunction layer; the mixed heterojunction layer comprised of tetraphenyldibenzoperiflanthene and C₇₀, located between the cathode buffer layer and an anode buffer layer; the anode buffer layer comprised of MoO₃, located between the mixed heterojunction layer and an anode layer; an anode layer comprised of indium tin oxide, adjacent to the anode buffer layer, wherein the photovoltaic cell is in an inverted configuration. In a particular embodiment, a 30 nm thick DBP:C₇₀ (1:8 vol. ratio) blend has an average transmission of T̅=59±2% between the wavelengths of λ=400 nm to 700 nm, and appears red owing to its reduced long wavelength absorption (inset, FIG. 1A).

The cathode buffer layer may have a thickness ranging from 5 to 500 nm, such as 5 to 250 nm, 5 to 150 nm, 10 to 125 nm, 10 to 100 nm, 10 to 90 nm, 20 to 70 nm, 20 to 60 nm and 20 to 40 nm. In certain embodiments, the cathode buffer layer has a thickness of 30 nm. The mixed heterojunction layer may have a thickness ranging from 5 to 500 nm, such as 5 to 250 nm, 5 to 150 nm, 10 to 125 nm, 10 to 100 nm, 10 to 90 nm, and 30 to 70 nm. In certain embodiments, the mixed heterojunction layer has a thickness of 30 nm, 40 nm, 50 nm, 60 nm, or 70 nm. The mixed heterojunction layer composition may range from a volume ratio of 1:1 to 1:16 of tetraphenyldibenzoperiflanthene and C₇₀, such as 1:12, 1:10, 1:8, 1:6, and 1:4. The anode buffer layer may have a thickness ranging from 2 to 500 nm, such as 5 to 250 nm, 5 to 100 nm, and 10 to 50 nm. In certain embodiments, the anode buffer layer has a thickness of 10 nm, 20 nm, 30 nm, 40 nm, or 50 nm.

In another embodiment of the present disclosure, an inverted photovoltaic cell comprises a cathode and an anode, both comprised of indium tin oxide; a cathode buffer, comprised of ZnO, adjacent to the cathode; an anode buffer, comprised of MoO₃, adjacent to the anode; and a mixed heterojunction comprised of tetraphenyldibenzoperiflanthene and C₇₀, adjacent to the cathode buffer and the anode buffer. The cathode buffer may have a thickness ranging from 5 to 500 nm, such as 5 to 250 nm, 5 to 150 nm, 10 to 125 nm, 10 to 100 nm, 10 to 90 nm, 20 to 70 nm, 20 to 60 nm and 20 to 40 nm. In certain embodiments, the cathode buffer has a thickness of 30 nm. The mixed heterojunction may have a thickness ranging from 5 to 500 nm, such as 5 to 250 nm, 5 to 150 nm, 10 to 125 nm, 10 to 100 nm, 10 to 90 nm, and 30 to 70 nm. In certain embodiments, the mixed heterojunction has a thickness of 30 nm, 40 nm, 50 nm, 60 nm, or 70 nm.

The mixed heterojunction composition may range from a volume ratio of 1:1 to 1:16 of tetraphenyldibenzoperiflanthene and Co, such as 1:12, 1:10, 1:8, 1:6, and 1:4. The anode buffer may have a thickness ranging from 2 to 500 nm, such as 5 to 250 nm, 5 to 100 nm, and 10 to 50 nm. In certain embodiments, the anode buffer has a thickness of 10 nm, 20 nm, 30 nm, 40 nm, or 50 nm.

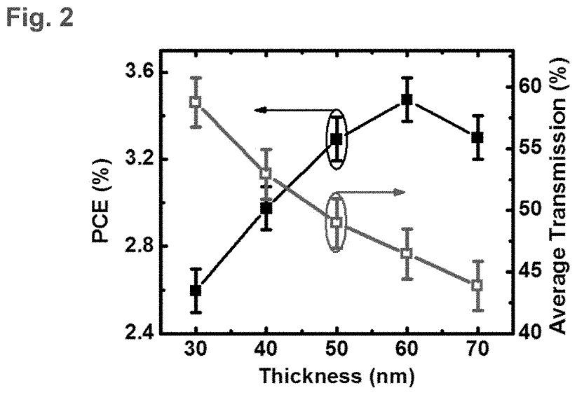

The J-V and EQE characteristics are shown in FIG. 1A and FIG. 1B with device performance summarized in Table I. The OPV cell with a 30 nm mixed heterojunction has a short circuit current density of J_{sc}=4.8±0.1 mA/cm², an open circuit voltage of V_{oc}=0.88±0.01 V, a fill factor of FF=0.61±0.01 and PCE=2.6±0.1% with T̅=59±2% across the visible as shown in the left inset, FIG. 1A. The cells with thicker photoactive layers exhibit increased EQE across the visible owing to enhanced absorption (FIG. 1B), thus leading to a correspondingly higher J_{sc}. While V_{oc} is independent of thickness, FF decreases with increasing heterojunction thickness due to increased series resistance. FIG. 2 shows a correlation between PCE and T̅ as a function of the photoactive layer thickness. The PCE and T̅ show opposite trends, with a maximum PCE=3.5±0.1% at a heterojunction thickness of 60 nm and T̅=47±2% across the visible. PCE decreases with further increases in thickness owing to reduction in FF.

To further understand the dependence of FF on x, the specific series resistance (R_{S}A) is obtained vs. the active layer thickness by filling the dark J-V characteristics to:

$$J ( V ) = {J}_{S} [ exp ( q \frac{[ V - J \cdot {R}_{S} A ]}{{nk}_{B} T} ) - χ ] - {J}_{p h} ( V ) \qquad ( 1 )$$

where Jₛ the saturation current density in the dark, n is the ideality factor associated with the donor (acceptor) layer, k_{B} is the Boltzmann constant, T is the temperature, q is the elementary charge, and Jₚₕ is the photocurrent density. χ is the ratio of the polaron-pair dissociation rate at the heterojunctions between donor and acceptor at V to its value at V=0. We find R_{S}A=2.9±0.1 Ω·cm² for 30 nm thick OPV cells, and increases to 5.8±0.1 Ω·cm² for 70 nm thick devices: a result of reduced charge collection efficiency (and hence FF) of thicker donor/acceptor mixed regions.

The inverted PM-HJ architecture consisting of a donor/acceptor mixture grown onto a neat acceptor layer is useful in reducing the active region series resistance by improving charge collection. Thus, an additional embodiment of the present disclosure is a semitransparent organic photovoltaic cell that comprises a cathode layer of tin oxide; a cathode buffer layer comprised of ZnO, located between the cathode layer and a planar-mixed heterojunction layer; the planar-mixed heterojunction layer comprised of a planar layer of C₇₀ and a mixed layer of tetraphenyldibenzoperiflanthene and C₇₀, located between the cathode buffer layer and an anode buffer layer; the anode buffer layer comprised of MoO₃, located between the mixed heterojunction layer and an anode layer; the anode layer comprised of indium tin oxide; wherein the photovoltaic cell is in an inverted configuration.

The cathode buffer layer may have a thickness ranging from 5 to 500 nm, such as 5 to 250 nm, 5 to 150 nm, 10 to 125 nm, 10 to 100 nm, 10 to 90 nm, 20 to 70 nm, 20 to 60 nm and 20 to 40 nm. In certain embodiments, the cathode buffer layer has a thickness of 30 nm. The planar heterojunction layer may have a thickness ranging from 2 to 16 nm, such as from 5 to 15 nm or 7 to 11 nm. In certain embodiments, the planar heterojunction layer has a thickness of 9 nm. The mixed heterojunction layer may have a thickness ranging from 5 to 500 nm, such as 5 to 250 nm, 5 to 150 nm, 10 to 125 nm, 10 to 100 nm, 10 to 90 nm, 20 to 70 nm, 20 to 60 nm, and 30 to 70 nm. In certain embodiments, the mixed heterojunction layer has a thickness of 51 nm. The percentage of planar heterojunction layer thickness in the planar-mixed heterojunction layer may range from 2 to 50%, such as 5 to 50%, 5 to 40%, 5 to 30%, 5 to 25%, 5 to 20%, 5 to 10%, 10 to 50%, 10 to 40%, 10 to 30%, 10 to 25%, 10 to 20%, 15 to 50%, 15 to 40%, 15 to 30%, 15 to 25%, 20 to 50%, 20 to 40%, and 20 to 30%. In certain embodiments, the percentage of planar heterojunction layer thickness in the planar-mixed heterojunction is 15%. The mixed heterojunction layer composition may range from a volume ratio of 1:1 to 1:16 of tetraphenyldibenzoperiflanthene and C₇₀, such as 1:12, 1:10, 1:8, 1:6, and 1:4. In certain embodiments, this ratio is 1:8. The anode buffer layer may have a thickness ranging from 2 to 500 nm, such as 5 to 250 nm, 5 to 100 nm, and 10 to 50 nm. In certain embodiments, the anode buffer layer has a thickness of 10 nm, 20 nm, 30 nm, 40 nm, or 50 nm. In certain embodiments, the semitransparent organic photovoltaic cell further comprises a second heterojunction layer.

In another embodiment of the present disclosure, an inverted photovoltaic cell comprises a cathode and an anode, both comprised of indium tin oxide; a cathode buffer, comprised of ZnO, adjacent to the cathode; an anode buffer, comprised of MoO₃, adjacent to the anode; and a planar-mixed heterojunction, comprising C₇₀ adjacent to the cathode buffer and a mixture of tetraphenyldibenzoperiflanthene and C₇₀ adjacent to the C₇₀ and the anode buffer. The cathode buffer may have a thickness ranging from 5 to 500 nm, such as 5 to 250 nm, 5 to 150 nm, 10 to 125 nm, 10 to 100 nm, 10 to 90 nm, 20 to 70 nm, 20 to 60 nm and 20 to 40 nm. In certain embodiments, the cathode buffer has a thickness of 30 nm. The C₇₀ layer may have a thickness ranging from 2 to 25 nm, such as from 5 to 15 nm or 7 to 11 nm. In certain embodiments, the C₇₀ layer is 9 nm thick. The layer comprising a mixture of tetraphenyldibenzoperiflanthene and C₇₀ may have a thickness ranging from 5 to 500 nm, such as 5 to 250 nm, 5 to 150 nm, 10 to 125 nm, 10 to 100 nm, 10 to 90 nm, 30 to 70 nm, and 40 to 60 nm. In certain embodiments, the layer comprising the mixture of tetraphenyldibenzoperiflanthene and Co has a thickness of 51 nm. The composition of the mixture of tetraphenyldibenzoperiflanthene and C₇₀ may range from a volume ratio of 1:1 to 1:16, such as 1:12, 1:10, 1:8, 1:6, and 1:4. In certain embodiments this ratio is 1:8. The anode buffer layer may have a thickness ranging from 2 to 500 nm, such as 5 to 250 nm, 5 to 150 nm, 10 to 125 nm, 10 to 100 nm, 10 to 90 nm, and 10 to 50 nm. In certain embodiments, the anode buffer layer has a thickness of 10 nm, 20 nm, 30 nm, 40 nm, or 50 nm.

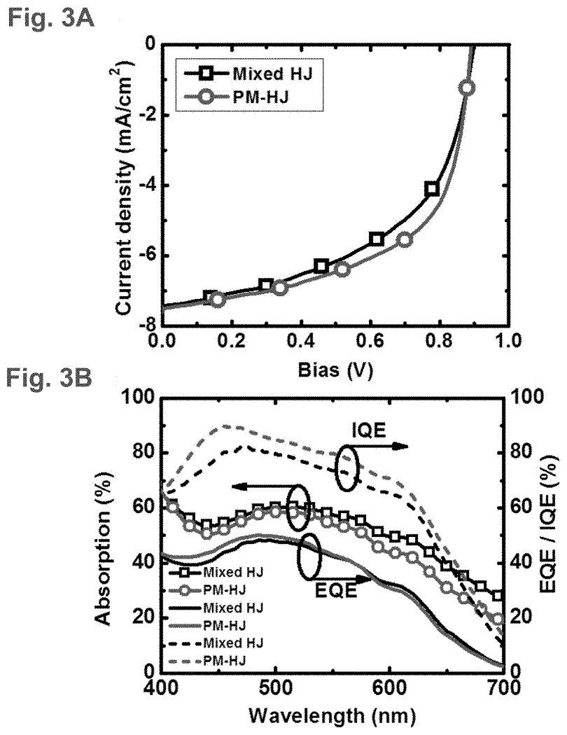

In certain embodiments, the neat C₇₀ layer thickness of 9 nm is roughly equal to its exciton diffusion length, leading to efficient exciton dissociation at the acceptor/blend interface. The C₇₀/DBP:C₇₀ film has T̅=51±2% across the visible, which is >10% higher than that of the mixed HJ. FIG. 3A shows the J-V characteristics of both the mixed heterojunction (HJ) and planar-mixed (PM)-HJ OPVs. The PM-HJ has a J_{sc}=7.5±0.2 mA/cm²; almost the same as the mixed HJ. Both cells have the same V_{oc}=0.89±0.01 V as expected, whereas FF increases from 0.53±0.01 for the mixed HJ to 0.58±0.01 for the PM-HJ due to a decrease in R_{S}A from 5.0±0.1 Ω·cm² to 3.8±0.1 Ω·cm². Therefore, the PCE of the PM-HJ OPV cell is increased to 3.9±0.2%, an 11% increase compared to the mixed HJ.

To further understand the improved combination of transparency and efficiency of the PM-HJ architecture, we measured the internal quantum efficiency (IQE), i.e. the ratio of photogenerated carriers collected at the electrodes to the absorbed photons in the active region. The PM-HJ shows reduced absorption, calculated using transfer matrices, compared to the mixed HJ, particularly between the wavelengths of λ=550 nm to 700 nm (see FIG. 3B). This results from a reduced amount of DBP in the photoactive region in the former structure. With a similar EQE for both architectures, the IQE of the PM-HJ is thus greater than that of the mixed HJ.

In another embodiment of the present disclosure, a tandem photovoltaic cell incorporates two PM-HJ sub-cells that absorb in different spectral regions; specifically, the embodiment contains a front sub-cell, a charge generation layer, and a back sub-cell. In some embodiments, the front sub-cell comprises a cathode layer comprised of indium tin oxide; a cathode buffer layer configured next to the cathode and comprised of ZnO; a planar-mixed heterojunction, comprised of a planar layer of C₇₀ configured next to the cathode buffer layer and a mixed layer of 2-((7-(5-(dip-tolyamino)thiophen-2-yl)benzo[c][1,2,5]thiadiazol4yl)methylene)malononitrile and C₆₀ configured next to the planar layer and the charge generation layer. In some embodiments, the front sub-cell may contain a mixed heterojunction, rather than a planar-mixed heterojunction. In some embodiments the charge generation layer may comprise a layer of MoO₃, configured next to the mixed layer of the front sub-cell; a layer of Ag, configured next to the layer of MoO₃; and a mixed layer comprising bathophenanthroline and C₇₀, configured next to the layer of Ag. In some embodiments, the back sub-cell comprises a planar-mixed heterojunction, comprised of a C₇₀ planar layer configured adjacent to the mixed layer of the charge generation layer, and a mixed layer of tetraphenyldibenzoperiflanthene and C₇₀, configured adjacent to the C₇₀ planar layer; a layer of MoO₃, configured adjacent to the mixed layer of the heterojunction; and a layer of indium tin oxide, configured adjacent to the layer of MoO₃. In some embodiments, the back sub-cell may contain a mixed heterojunction, rather than a planar-mixed heterojunction.

The cathode buffer layer may range in thickness from 5 to 500 nm, such as 5 to 250 nm, 5 to 150 nm, 10 to 125 nm, 10 to 100 nm, 10 to 90 nm, 20 to 70 nm, 20 to 60 nm and 20 to 40 nm. In certain embodiments, the cathode buffer layer has a thickness of 30 nm. The thickness of the front sub-cell planar heterojunction layer may range from 1 to 16 nm, such as from 2 to 11 nm or 3 to 8 nm. In certain embodiments, the front sub-cell planar heterojunction layer is 5 nm.

The front sub-cell mixed heterojunction layer may range from thicknesses of 5 to 500 nm, such as 5 to 250 nm, 5 to 150 nm, 10 to 125 nm, 10 to 100 nm, 10 to 90 nm, and 30 to 70 nm. In certain embodiments, the front sub-cell mixed heterojunction layer has a thickness of 60 nm. The front sub-cell mixed heterojunction layer composition may range from a volume ratio of 5:1 to 1:5 of 2-((7-(5-(dip-tolyamino)thiophen-2-yl)benzo[c][1,2,5]thiadiazol4yl)methylene)malononitrile and C₆₀, such as 4:1, 3:1, 2:1, 1:1, 1:2, 1:3, and 1:4. In certain embodiments, this ratio is 1:1.

The layer of MoO₃ present in the charge generation layer may have a thickness ranging from 5 to 100 nm, such as 5 to 75 nm, 10 to 50 nm, 10 to 40 nm, 15 to 50 nm, 15 to 40 nm, and 15 to 30 nm. In certain embodiments, the layer of MoO₃ present in the charge generation layer has a thickness of 20 nm. The layer of Ag present in the charge generation layer may range in thickness from 0.01 to 1 nm, such as 0.05 to 1 nm, 0.05 to 0.75 nm, 0.05 to 0.5 nm, 0.05 to 0.25 nm, 0.1 to 0.5 nm, and 0.1 to 0.25 nm. In certain embodiments, the layer of Ag present in the charge generation layer is 0.1 nm. The mixed layer of bathophenanthroline and C₆ present in the charge generation layer may range in thickness from 2 to 50 nm, such as 2 to 40 nm, 2 to 30 nm, 2 to 20 nm, 3 to 40 nm, 3 to 30 nm, 3 to 20 nm, 4 to 30 nm, 4 to 20 nm, and 4 to 10 nm. In certain embodiments the mixed layer of bathophenanthroline and Co in the charge generation layer has a thickness of 5 nm. The composition of the mixed layer of bathophenanthroline and C₆₀ in the charge generation layer may range from 5:1 to 1:5 by volume, such as 4:1, 3:1, 2:1, 1:1, 1:2, 1:3, and 1:4. In certain embodiments the volume ratio of bathophenanthroline and Co is 1:1.

The back sub-cell planar heterojunction layer may have a thickness ranging from 1 to 16 nm, such as from 2 to 11 nm or 5 to 9 nm. In certain embodiments, the back sub-cell planar heterojunction layer is 7 nm. The back sub-cell mixed heterojunction layer may have a thickness ranging from 5 to 500 nm, such as 5 to 250 nm, 5 to 150 nm, 10 to 125 nm, 10 to 100 nm, 10 to 90 nm, and 30 to 70 nm. In certain embodiments, the back sub-cell mixed heterojunction layer has a thickness of 55 nm. The back sub-cell mixed heterojunction layer composition may range from a volume ratio of 1:1 to 1:16 of tetraphenyldibenzoperiflanthene and C₇₀, such as 1:12, 1:10, 1:8, 1:6, and 1:4 In certain embodiments, the volume ratio of tetraphenyldibenzoperiflanthene and C₇₀ is 1:8. The anode buffer layer may have a thickness ranging from 2 to 500 nm, such as 5 to 250 nm, 5 to 150 nm, 10 to 125 nm, 10 to 100 nm, 10 to 90 nm, and 10 to 50 nm. In certain embodiments, the anode buffer layer has a thickness of 20 nm.

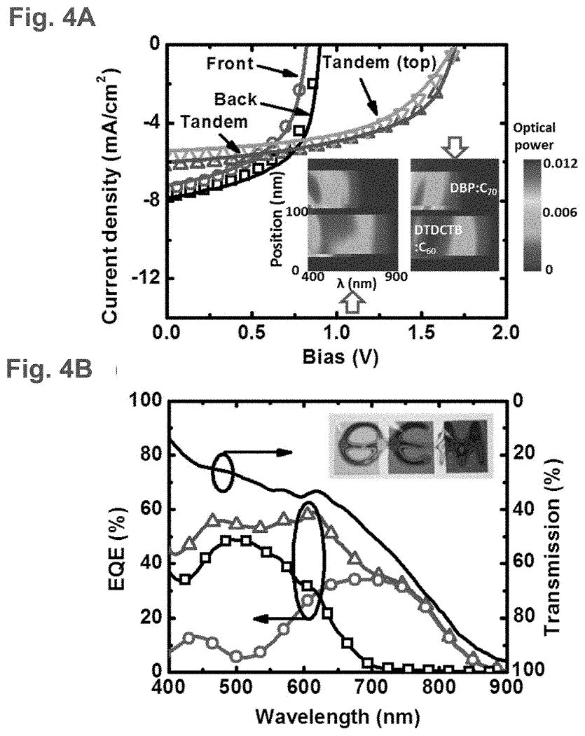

FIG. 4A shows J-V characteristics of discrete sub-cells (fabricated for comparison purposes) and the tandem cells, with their performances summarized in Table I. The calculated optical absorption of the sub-cells is plotted in the inset of FIG. 4A. The DTDCTB:C₆₀ and DBP:C₇₀ films appear green and red (see FIG. 4B, inset), respectively, owing to their different absorption spectra, while the tandem film has a neutral appearance due to its broader absorption. Hence, depending on the needs of a particular application, single junction cells can be designed to have a pastel tint, whereas the more absorptive and efficient tandem cell has a neutral coloration.

FIG. 4B also shows the external quantum efficiencies (EQE) of the discrete and tandem cells. For the tandem cell V_{oc}=1.70±0.01 V, which is almost equal to the sum of two sub-cells, indicating that the CGL is electrically lossless. Furthermore, J_{SC}=6.2±0.2 mA/cm² for the tandem is less than that of the individual sub-cells mainly due to the slight overlap of their individual absorption spectra. The tandem cell has FF=0.51±0.01, limited by that of the DTDCTB:C₇₀ PM-HJ. Overall, the optimized tandem cell exhibits PCE=5.3±0.3% under simulated AM 1.5G illumination at one sun intensity, with T̅=31±1% across the visible.

Previously, thin metal films have been employed as semitransparent cathodes in OPV cells. These films, however, reflect and absorb a significant fraction of the incident light. which dramatically reduces the efficiency of the device when illuminated via the cathode vs. the anode. In the present disclosure, the use of metal-free, transparent ITO for both contacts eliminates these reflections and optical losses. As shown in the inset of FIG. 4A, the optical fields within the two sub-cells are only slightly different when light is incident from opposite device surfaces. Top illuminated tandem cells have J_{SC}=5.8±0.2 mA/cm² compared to 6.2±0.2 mA/cm² for bottom illumination, yielding PCE=4.9±0.3% vs. 5.3±0.3%, respectively.

Various devices made according to the foregoing disclosures were made and tested. The embodiments described herein are further illustrated by the following non-limiting examples.

### EXAMPLES

The photovoltaic cells were grown on glass substrates with pre-patterned ITO (4.2 mm×3.5 mm patterns, sheet resistance: 15 f/sq). The glass/ITO substrates were cleaned by successive ultrasonication in tergitol, deionized water, and a series of organic solvents, followed by ultraviolet ozone exposure for 10 min. The ITO surface was coated with ZnO deposited using a precursor solution prepared by dissolving 0.5 M zinc acetate dihydrate in 2-methoxyethanol with ethanolamine added as a stabilizer. The solution was passed through a 0.45 μm pore, polyvinylidene fluoride filter, and then spun-cast onto the substrates at 3000 rpm for 30 s. The film was then thermally annealed in ambient at 150° C. for 30 min. The substrates were transferred into a high vacuum chamber with a base pressure of 10⁻⁷ torr where organic layers were deposited. Top contacts consisting of 100 nm thick ITO were sputter-deposited at a base pressure of 7×10⁻⁸ torr and a deposition rate of 0.04 nm/s through a shadow mask with an array of 11 mm² openings oriented perpendicular to the ITO contact patterns on the substrate. Completed devices were directly transferred into a high-purity N₂-filled glove box with both H₂O and O₂ concentrations of <0.1 ppm. There, current density-voltage (J-V) and external quantum efficiency (EQE) measurements were performed. Transmission spectra of unpatterned films were obtained using a spectrometer (Perkin-Elmer, LAMBDA 1050).

What is claimed is:

1. A semitransparent organic photovoltaic cell, comprising:
a cathode layer comprised of indium tin oxide;
a cathode buffer layer comprised of ZnO, located between the cathode layer and a mixed heterojunction layer;
the mixed heterojunction layer comprised of tetraphenyldibenzoperiflanthene and C₇₀, located between the cathode buffer layer and an anode buffer layer;
the anode buffer layer comprised of MoO₃, located between the mixed heterojunction layer and an anode layer; and
an anode layer comprised of indium tin oxide, adjacent to the anode buffer layer,
wherein the photovoltaic cell is in an inverted configuration.

2. The semitransparent organic photovoltaic cell of claim 1, wherein the cathode buffer layer comprised of ZnO has a thickness ranging from 20 to 60 nm.

3. The semitransparent organic photovoltaic cell of claim 1, wherein the mixed heterojunction layer has a thickness ranging from 30 nm to 70 nm.

4. The semitransparent organic photovoltaic cell of claim 1, wherein the anode buffer layer comprised of MoO₃ has a thickness ranging from 10 to 50 nm.

5. The semitransparent organic photovoltaic cell of claim 1, wherein the mixed heterojunction layer is comprised of a 1:8 volume ratio of tetraphenyldibenzoperiflanthene and C₇₀.

6. The semitransparent organic photovoltaic cell of claim 1, further comprising a planar heterojunction layer comprising C₇₀ located between the cathode buffer layer and the mixed heterojunction layer.

7. A semitransparent organic photovoltaic cell, comprising:
a cathode layer comprised of indium tin oxide;
a cathode buffer layer comprised of ZnO, located between the cathode layer and a planar-mixed heterojunction layer;
the planar-mixed heterojunction layer comprised of a planar layer of C₇₀ and a mixed layer of tetraphenyldibenzoperiflanthene and C₇₀, located between the cathode buffer layer and an anode buffer layer;
the anode buffer layer comprised of MoO₃, located between the mixed heterojunction layer and an anode layer; and
the anode layer comprised of indium tin oxide,
wherein the photovoltaic cell is in an inverted configuration.

8. The semitransparent organic photovoltaic cell of claim 7, wherein the cathode buffer layer comprised of ZnO has a thickness ranging from 20 to 60 nm.

9. The semitransparent organic photovoltaic cell of claim 7, wherein the planar heterojunction layer has a thickness ranging from 7-11 nm.

10. The semitransparent organic photovoltaic cell of claim 7, wherein the mixed heterojunction layer has a thickness ranging from 45-55 nm in width.

11. The semitransparent organic photovoltaic cell of claim 7, wherein the thickness of the planar layer in the planar-mixed heterojunction comprises 15% of the width of the planar-mixed heterojunction.

12. The semitransparent organic photovoltaic cell of claim 7, wherein the anode buffer comprised of MoO₃ has a thickness of 20 nm.

13. The semitransparent organic photovoltaic cell of claim 7, wherein the composition of the mixed heterojunction is a 1:8 volume ratio of tetraphenyldibenzoperiflanthene and C₇₀.

14. The semitransparent organic photovoltaic cell of claim 7, wherein the photovoltaic cell further comprises a second heterojunction layer.

15. A tandem photovoltaic cell comprising:
a front sub-cell, a back sub-cell, and a charge generation layer configured between the front sub-cell and the back sub-cell,
wherein the front sub-cell comprises
a cathode layer comprised of indium tin oxide;
a cathode buffer layer configured next to the cathode and comprised of ZnO; and
a front sub-cell heterojunction, comprised of 2-((7-(5-(dip-tolyamino)thiophen-2-yl)benzo[c][1,2,5]thiadiazol4yl)methylene)malononitrile and C₆₀, configured next to the cathode buffer layer and the charge generation layer.

16. The tandem photovoltaic cell of claim 15, wherein the front sub-cell heterojunction is a planar-mixed heterojunction, comprised of a planar layer of C₆₀ configured next to the cathode buffer layer and a mixed layer of 2-((7-(5-(dip-tolyamino)thiophen-2-yl)benzo[c][1,2,5]thiadiazol4yl)methylene)malononitrile and C₆₀ configured next to the planar layer and the charge generation layer.

17. The tandem photovoltaic cell of claim 15, wherein the charge generation layer comprises a layer of MoO₃, configured next to the heterojunction of the front sub-cell; a layer of Ag, configured next to the layer of MoO₃; and a mixed layer comprising bathophenanthroline and C₆₀, configured next to the layer of Ag.

18. The tandem photovoltaic cell of claim 15, wherein the back sub-cell comprises a back sub-cell heterojunction, configured adjacent to the charge generation layer; a layer of MoO₃, configured adjacent to the heterojunction; and a layer of indium tin oxide, configured adjacent to the layer of MoO₃.

19. The tandem voltaic cell of claim 15, wherein the back sub-cell comprises a planar-mixed heterojunction, comprised of a C₇₀ planar layer configured adjacent to the charge generation layer, and a mixed layer of tetraphenyldibenzoperiflanthene and C₇₀, configured adjacent to the C₇₀ planar layer; a layer of MoO₃ configured adjacent to the mixed layer of the heterojunction; and a layer of indium tin oxide configured adjacent to the layer of MoO₃.

20. The tandem voltaic cell of claim 15,
wherein the cathode buffer layer has a thickness ranging from 20-60 nm,
wherein the front sub-cell heterojunction is a planar-mixed heterojunction, comprised of a planar layer of C₆₀ having a thickness ranging from 2 to 20 nm, configured next to the cathode buffer layer and a mixed layer of 2-((7-(5-(dip-tolyamino)thiophen-2-yl)benzo[c][1,2,5]thiadiazol4yl)methylene)malononitrile and C₆₀ having a thickness ranging from 40 to 100 nm and a composition of 1:1 volume ratio, configured next to the planar layer and the charge generation layer,
wherein the charge generation layer comprises a layer of MoO₃ having a thickness ranging from 5 to 45 nm, configured next to the mixed layer of the front sub-cell; a layer of Ag having a thickness ranging from 0.01 to 1 nm, configured next to the layer of MoO₃; and a mixed layer comprising bathophenanthroline and C₆₀ having a thickness ranging from 2 to 15 nm and a composition of 1:1 volume ratio, configured next to the layer of Ag,
wherein the back sub-cell comprises a planar-mixed heterojunction, comprised of a C₇₀ planar layer having a thickness ranging from 2 to 15 nm, configured adjacent to the mixed layer of the charge generation layer, and a mixed layer of tetraphenyldibenzoperiflanthene and C₇₀ with a thickness ranging from 45 to 65 nm and a composition of 1:8 volume ratio, configured adjacent to the C₇₀ planar layer; a layer of MoO₃ having a thickness ranging from 5 to 40 nm, configured adjacent to the mixed layer of the heterojunction; and a layer of indium tin oxide having a thickness ranging from 50 to 150 nm, configured adjacent to the layer of MoO₃.
